(19) United States
(12) Patent Application Publication
(10) Pub. No.: US 2021/0395442 A1
(43) Pub. Date: Dec. 23, 2021

(54) TERPOLYMER BASED ON 2,5-BIS(2-THIENYL)THIAZOLO[5,4-D]THIAZOLYL

(71) Applicant: SOOCHOW UNIVERSITY, Suzhou (CN)

(72) Inventors: Maojie ZHANG, Suzhou (CN); Jingnan WU, Suzhou (CN); Xia GUO, Suzhou (CN)

(21) Appl. No.: 17/284,462

(22) PCT Filed: Jul. 16, 2020
(86) PCT No.: PCT/CN2020/102360

§ 371 Date: Apr. 10, 2021

(30) Foreign Application Priority Data
Oct. 23, 2019 (CN) 201911012216.9

(51) Int. Cl. C08G 61/12

(52) U.S. Cl. CPC C08G 61/126; C08G 2261/3223; C08G 2261/3246; C08G 2261/95; C08G 2261/122; C08G 2261/40; C08G 2261/91; C08G 2261/3243

(57) ABSTRACT

The present invention discloses a terpolymer based on 2,5-bis(2-thienyl)thiazolo[5,4-d]thiazolyl. In the invention, by introducing 2,5-bis(2-thienyl)thiazolo[5,4-d]thiazole units, the conjugated length of the polymers is enlarged and the aggregation in solution becomes weak. The introducing of 2,5-bis(2-thienyl)thiazolo[5,4-d]thiazole unit can easily tune the photophysical properties and the aggregation structure of the terploymers, and the terpolymers show excellent photovoltaic performance. The terpolymers have the following general formula:

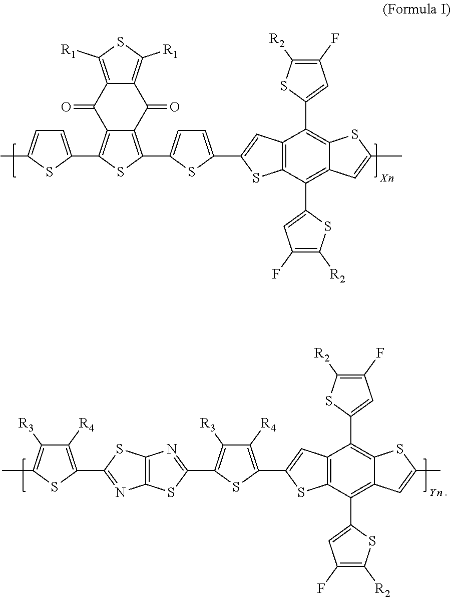

### FIELD OF THE INVENTION

The present invention relates to the field of molecular technology, and more particularly to a terpolymer based on 2,5-bis(2-thienyl)thiazolo[5,4-d]thiazolyl and a preparation method thereof, and use of the terpolymer as an active layer material in organic semiconductor devices such as organic solar cells and organic field effect transistors, organic electroluminescent devices, organic thermochromic components, and organic field effect transistors.

### DESCRIPTION OF THE RELATED ART

It has always been a research hotspot and difficulty to use inexpensive materials to prepare low-cost and high-efficiency solar cells in the photovoltaic field. Currently the application of crystalline silicon solar cells used on the ground is limited due to the complex production process and high cost. To reduce the cell cost and widen the scope of application, new solar cell materials are sought for a long period of time. Organic semiconductor materials have attracted much attention because of its easily available and inexpensive raw materials, simple preparation process, excellent environmental stability, and good photovoltaic effect. Since the concept of bulk heterojunction was first proposed and the world's first single-layer bulk-heterojunction (BHJ) organic solar cell was produced by Heeger et al. with the conjugated polymer MEH-PPV as an electron donor material and the fullerene derivative PCBM as an electron acceptor material in 1995, extensive research are focused on polymer solar cells and rapid development is achieved (G. Yu, J. G., J. C. Hummelen, F. Wudi, A. J. Heeger, Science, 1995, 270 (5243); L. Meng, Y. Zhang, X. Wan, C. Li, X. Zhang, Y. Wang, X. Ke, Z. Xiao, L. Ding, R. Xia, H. L. Yip, Y. Cao and Y. Chen, science. 2018, 361, 1094; J. Yuan, Y. Zhang, L. Zhou, G. Zhang, H.-L. Yip, T.-K. Lau, X. Lu, C. Zhu, H. Peng, P. A. Johnson, M. Leclerc, Y. Cao, J. Ulanski, Y. Li and Y. Zou, Joule. 2019, 3, 1; W. Su, Q. Fan, X. Guo, J. Chen, Y. Wang, X. Wang, P. Dai, C. Ye, X. Bao, W. Ma, M. Zhang and Y. Li, Journal of Materials Chemistry A. 2018, 6, 7988; M. Zhang, Y. Gu, X. Guo, F. Liu, S. Zhang, L. Huo, T. P. Russell and J. Hou, Adv Mater. 2013, 25, 4944; and M. Zhang, X. Guo, W. Ma, H. Ade and J. Hou, Adv Mater. 2014, 26, 5880. M. Zhang, X. Guo, W. Ma, H. Ade and J. Hou, Adv Mater. 2015, 27, 4655.). However, the conversion efficiency is still much lower than that of inorganic solar cells. The main constraints limiting the improvement of performance include mismatched spectral response of organic semiconductor materials with the solar radiation spectrum, relatively low carrier mobility of organic semiconductors, and low collection efficiency of carriers in the electrode.

Therefore, the present invention aims to develop a new material to greatly improve the energy conversion efficiency.

### SUMMARY OF THE INVENTION

An object of the present invention is to provide a terpolymer based on 2,5-bis(2-thienyl)thiazolo[5,4-d]thiazolyl, and a preparation method and use thereof.

In one aspect, the present invention provides a terpolymer based on 2,5-bis(2-thienyl)thiazolo[5,4-d]thiazolyl having a general formula of:

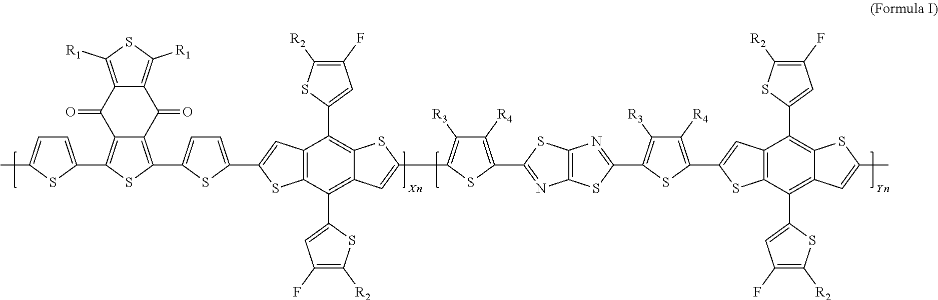

wherein:

R₁ is selected from an alkyl group having 1-30 carbon atoms;

R₂, R₃ and R₄ are independently selected from the group consisting of hydrogen, an alkyl group having 1-30 carbon atoms, an alkyloxy group having 1-30 carbon atoms, an ester group, an aryl group, an aralkyl group, a haloalkyl group, a heteroalkyl group, an alkenyl group and an aryl group substituted by a substituent group containing a single bond, a double bond, a triple bond or any combination thereof;

n represents the number of repeating units in the polymer, and is selected from a natural number between 1-5000; and

X and Y are independently selected from decimals between 0-1, and the sum of X and Y is equal to 1.

Preferably, the terpolymer based on 2,5-bis(2-thienyl)thiazolo[5,4-d]thiazolyl has a number average molecular weight of 1000 to 1,000,000.

In another aspect, the present invention provide a method for preparing a terpolymer based on 2,5-bis(2-thienyl)thiazolo[5,4-d]thiazolyl, which comprises subjecting a compound of Formula II, a compound of Formula III, and a compound of Formula IV to ternary random copolymerization in the presence of a catalyst:

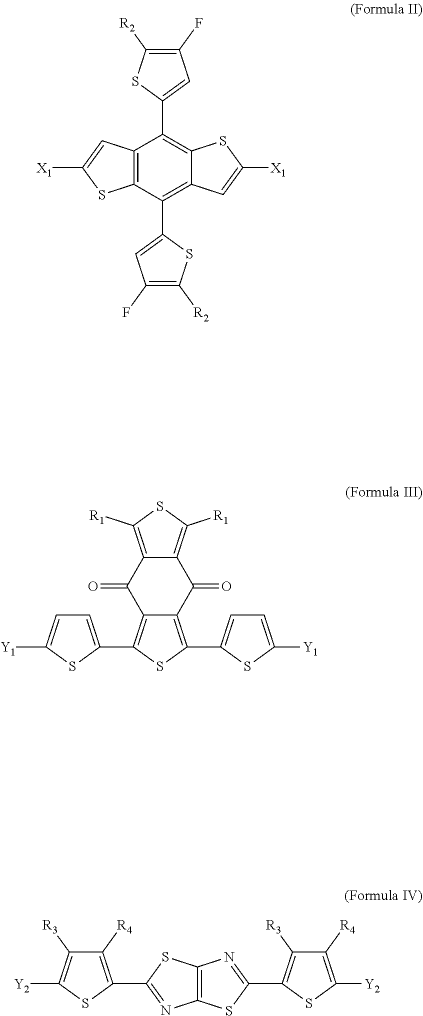

wherein:

R₁ is selected from any of an alkyl group having 1-30 carbon atoms;

R₂, R₃ and R₄ are independently selected from the group consisting of hydrogen, an alkyl group having 1-30 carbon atoms, an alkoxy group having 1-30 carbon atoms, an ester group, an aryl group, an aralkyl group, a haloalkyl group, a heteroalkyl group, an alkenyl group, and an aryl group substituted by a substitute group containing a single bond, a double bond, a triple bond or a combination thereof;

X₁ is selected from the group consisting of a boric acid group, a borate ester group, a zinc halide group and a trialkyltin group; and

Y₁ and Y₂ are independently selected from I, Br or Cl.

Preferably, the boric acid group is any one selected from 1,3,2-dioxaboran-2-yl, 4,4,5,5-tetramethyl-1,2,3-dioxaborolan-2-yl or 5,5-dimethyl-1,3,2-dioxaboran-2-yl; the zinc halide group is selected from zinc chloride group or zinc bromide group; and the trialkyltin group is selected from trimethyl tin, triethyl tin or tributyl tin.

Preferably, the catalyst is selected from the group consisting of [1,3-bis(diphenylphosphino)propane]nickel dichloride, tetrakis(triphenylphosphine)palladium, [1,2-bis(diphenylphosphino)ethane]nickel chloride, bis(dibenzalacetone)palladium, palladium chloride, palladium acetate and any combination thereof.

Preferably, the molar ratio of the compound of Formula III to the compound of Formula IV is 100:0-100:100 to 0:100-100:100.

Preferably, the reaction temperature is 80-200° C., and the reaction time is 6-48 h.

Use of the terpolymer based on 2,5-bis(2-thienyl)thiazolo[5,4-d]thiazolyl prepared by the above method in thin film semiconductor devices, electrochemical devices, photovoltaic devices and photoelectric devices is further provided.

The present invention provides a terpolymer based on 2,5-bis(2-thienyl)thiazolo[5,4-d]thiazolyl. A terpolymer is obtained by introducing a 2,5-bis(2-thienyl)thiazolo[5,4-d]thiazolyl unit as a third component to the backbone of a fluorine-containing substituted DA conjugated polymer (for example: PM6). The polymer has the advantages of solution processability (soluble in organic solvents such as chloroform, tetrahydrofuran, and chlorobenzene), good thermal stability (the initial thermal decomposition temperature is higher than 410° C.), high light absorbency, and suitable electronic energy level, and can effectively reduce the energy level of the polymer without affecting the optical band gap of the polymer, thereby improving the open circuit voltage and the photoelectric conversion efficiency of the device.

### BRIEF DESCRIPTION OF THE DRAWINGS

In order to more clearly illustrate the technical solutions in the embodiments of the present invention, the drawings used in the embodiments will be briefly described below. Obviously, the drawings depicted below are merely embodiments of the present invention, and those skilled in the art can obtain other drawings based on these drawings without any creative efforts, in which:

FIG. 1 shows a thermogravimetric analysis curve of a terpolymer based on 2,5-bis(2-thienyl)thiazolo[5,4-d]thiazolyl in Example 1 of the present invention;

FIG. 2 shows a ultraviolet-visible absorption spectrum of the terpolymer based on 2,5-bis(2-thienyl)thiazolo[5,4-d]thiazolyl in Example 1 of the present invention;

FIG. 3 shows a cyclic voltammetry curve of the terpolymer based on 2,5-bis(2-thienyl)thiazolo[5,4-d]thiazolyl in Example 1 of the present invention;

FIG. 4 shows a J-V curve of an organic solar cell where the terpolymer based on 2,5-bis(2-thienyl)thiazolo[5,4-d]thiazolyl in Example 1 of the present invention is used;

FIG. 5 shows an external quantum efficiency (EQE) curve of an organic solar cell where the terpolymer based on 2,5-bis(2-thienyl)thiazolo[5,4-d]thiazolyl in Example 1 of the present invention is used;

FIG. 6 shows a thermogravimetric analysis curve of a terpolymer based on 2,5-bis(2-thienyl)thiazolo[5,4-d]thiazolyl in Example 2 of the present invention;

FIG. 7 shows a ultraviolet-visible absorption spectrum of the terpolymer based on 2,5-bis(2-thienyl)thiazolo[5,4-d]thiazolyl in Example 2 of the present invention;

FIG. 8 shows a cyclic voltammetry curve of the terpolymer based on 2,5-bis(2-thienyl)thiazolo[5,4-d]thiazolyl in Example 2 of the present invention;

FIG. 9 shows a J-V curve of an organic solar cell where the terpolymer based on 2,5-bis(2-thienyl)thiazolo[5,4-d]thiazolyl in Example 2 of the present invention is used; and

FIG. 10 shows an external quantum efficiency (EQE) curve of an organic solar cell where the terpolymer based on 2,5-bis(2-thienyl)thiazolo[5,4-d]thiazolyl in Example 2 of the present invention is used.

### DETAILED DESCRIPTION OF THE PREFERRED EMBODIMENTS

In the present invention, a 2,5-bis(2-thienyl)thiazolo[5,4-d]thiazole unit is introduced into the backbone of a fluorine-containing substituted DA conjugated polymer (for example: PM6), and relevant properties of the polymer material are adjusted by adjusting the modification of functional groups on the donor and acceptor units and the length of the alkyl chain, so that the resulting polymer has a lower electronic energy level, a better molecular arrangement and a higher hole mobility while its optical band gap is not substantially affected, thereby achieving excellent photovoltaic performance of device.

The polymer provided in the present invention has a structural formula below:

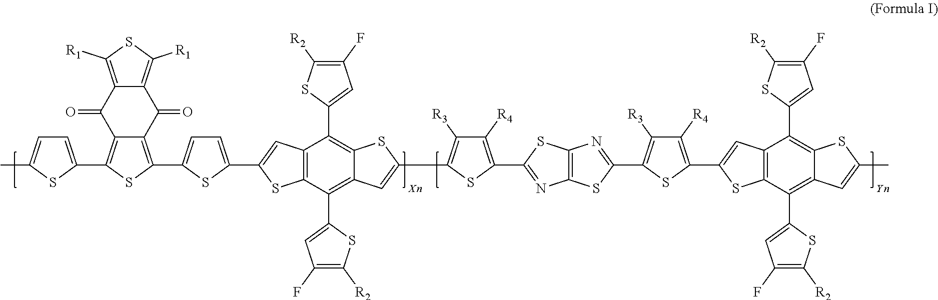

wherein:

R₁ is an alkyl group having 1-30 carbon atoms;

R₂, R₃ and R₄ are independently selected from the group consisting of hydrogen, an alkyl group having 1-30 carbon atoms, an alkoxy group having 1-30 carbon atoms, an ester group, an aryl group, an aralkyl group, a haloalkyl group, a heteroalkyl group, an alkenyl group, and an aryl group substituted by a substitute group containing a single bond, a double bond, a triple bond or any combination thereof;

n represents the number of repeating units in the polymer, and is selected from a natural number between 1-5000; and

X and Y are independently selected from decimals between 0-1, and the sum of X and Y is equal to 1.

The terpolymer based on 2,5-bis(2-thienyl)thiazolo[5,4-d]thiazolyl has a number average molecular weight of 1000 to 1,000,000.

A method for preparing a terpolymer based on 2,5-bis(2-thienyl)thiazolo[5,4-d]thiazolyl comprises subjecting a compound of Formula II, a compound of Formula III, and a compound of Formula IV to ternary random copolymerization in the presence of a catalyst at a reaction temperature of 80-200° C. for 6-48 h, to obtain a polymer of Formula I:

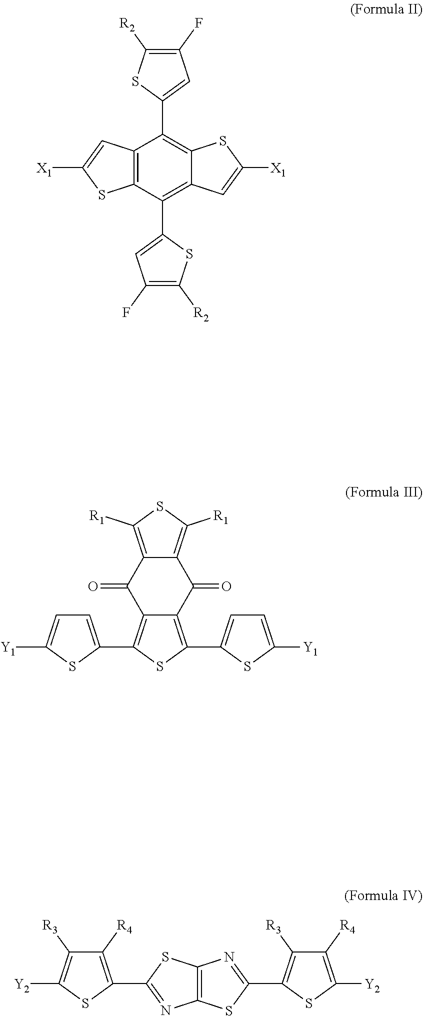

wherein:

R₁ is an alkyl group having 1-30 carbon atoms;

R₂, R₃ and R₄ are independently selected from the group consisting of hydrogen, alkyl group having 1-30 carbon atoms, an alkyloxy group having 1-30 carbon atoms, an ester group, an aryl group, an aralkyl group, a haloalkyl group, a heteroalkyl group, an alkenyl group, and an aryl group substituted by a substitute group containing a single bond, a double bond, a triple bond or any combination thereof;

X₁ is selected from the group consisting of a boric acid group, a borate ester group, a zinc halide group and a trialkyltin group; and

Y₁ and Y₂ are selected from I, Br or Cl.

The catalyst is selected from the group consisting of [1,3-bis(diphenylphosphino)propane]nickel dichloride, tetrakis(triphenylphosphine)-palladium, [1,2-bis(diphenylphosphino)ethane]nickel chloride, bis(dibenzalacetone)-palladium, palladium chloride or palladium acetate. The boric acid group is selected from 1,3,2-dioxaboran-2-yl, 4,4,5,5-tetramethyl-1,2,3-dioxaborolan-2-yl or 5,5-dimethyl-1,3,2-dioxaboran-2-yl. The zinc halide group is zinc chloride group or zinc bromide group. The trialkyltin group is trimethyl tin, triethyl tin or tributyl tin. The molar ratio of the compound of Formula III to the compound of Formula IV is 100:0-100:100 to 0:100-100:100.

The present invention also provides use of the terpolymer based on 2,5-bis(2-thienyl)thiazolo[5,4-d]thiazolyl in the production of thin film semiconductor devices, electrochemical devices, photovoltaic devices and photoelectric devices. The device is specifically a polymer solar cell device or a photodetector device, and the polymer solar cell device is further a polymer solar cell device including a bulk heterojunction structure.

The terpolymer based on 2,5-bis(2-thienyl)thiazolo[5,4-d]thiazolyl of the present invention is blended with dopants to compose the active layer, where the dopant is selected from a fullerene derivative or a non-fullerene N-type organic semiconductor.

When the terpolymer based on 2,5-bis(2-thienyl)thiazolo[5,4-d]thiazolyl is used in a photovoltaic device, the photovoltaic device includes a hole collecting layer, an electron collecting layer, and a photovoltaic material layer between the hole collecting layer and the electron collecting layer, where the photovoltaic material layer contains the conjugated polymer. When the terpolymer based on 2,5-bis(2-thienyl)thiazolo[5,4-d]thiazolyl is used in an photoelectric device, the photoelectric device includes a first electrode, a second electrode spaced apart from the first electrode, and at least one active material layer provided between the first electrode and the second electrode, where the active material layer contains the conjugated polymer.

To make the above objects, features and advantages of the present invention more apparent, the technical solution of the present invention will be further described below with reference to accompanying drawings and specific embodiments. However, the invention is not limited to the embodiments shown, and any other known variations should be contained within the scope of the invention as claimed.

First, “an embodiment” or “embodiments” as used herein refers to a particular feature, structure, or characteristic that can be included in at least one implementation of the invention. The expressions of “in one embodiment” in different places of the specification do not refer to the same embodiments, nor are they separate or selective embodiments that are mutually exclusive.

The present invention is described in detail with reference to the schematic structural views. In the detailed description of the embodiments of the present invention, the schematic views are partially enlarged in accordance with a non-general scale for ease of description, and the schematic views are only illustrative and not intended to limit the scope of protection of the present invention. In addition, the actual production should include three-dimensional space in length, width and depth.

### Example 1

1. Synthesis of terpolymer PM6-TTz20

The chemical reaction route in this example is shown below, and the specific reaction steps and conditions are as follows.

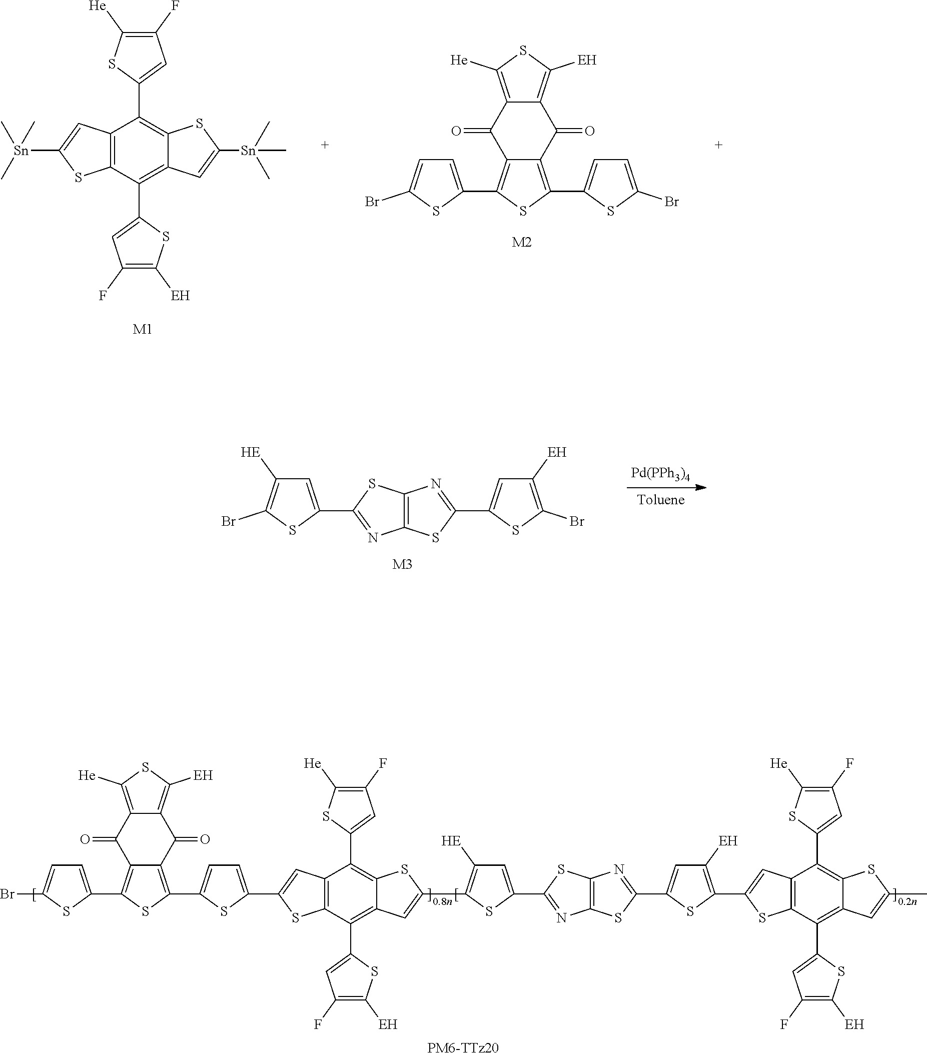

To a 50 mL two-neck round-bottom flask, 0.3 mmol of a ditin monomer M1, 0.24 mmol of a dibromide monomer M2, 0.06 mmol of a dibromide monomer M3, and 10 mL of anhydrous toluene were added. After argon was introduced for 20 min to the reaction flask, 15 mg of Pd(PPh₃)₄ was added to the flask as a catalyst, and then argon was introduced to the reaction mixture for 30 min. The reaction mixture was stirred and refluxed for 7 h under argon atmosphere. After the polymerization, the reaction mixture was cooled to room temperature, and then the polymer was settled in 100 mL of HPLC-grade methanol. The solid was collected by filtration, and finally subjected to Soxhlet extraction with HPLC-grade methanol, n-hexane and chloroform. The chloroform extract was concentrated and settled in HPLC-grade methanol, to obtain the solid polymer PM6-TTz20, which was dried under vacuum. Using trichlorobenzene as a solvent, the polymer is measured by gel permeation chromatography to have a number average molecular weight (Mₙ) of 28.7 kDa and a polydispersity index (PDI) of 1.98.

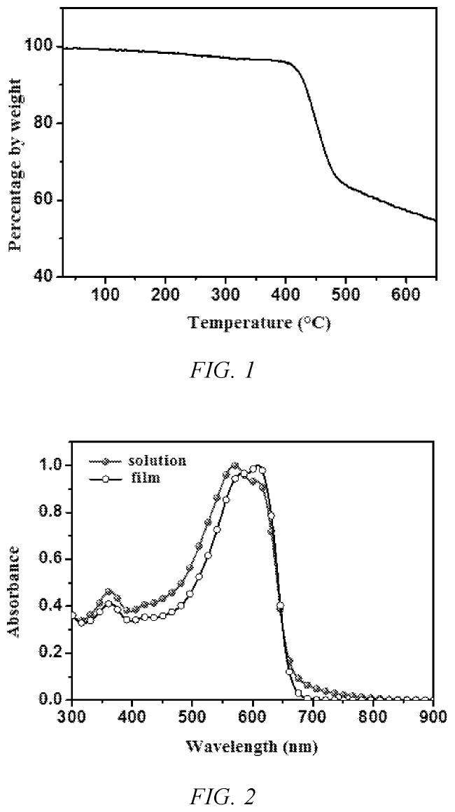

The polymer PM6-TTz20 prepared above was subjected to thermogravimetric analysis under a nitrogen atmosphere. The results are shown in FIG. 1. FIG. 1 shows that the decomposition temperature of the polymer PM6-TTz20 at a weight loss of 5% is 411° C., which indicates that the polymer has good thermal stability.

The polymer PM6-TTz20 prepared above was mixed with various organic solvents. It is found that the polymer PM6-TTz20 has good solubility in toluene, chloroform, chlorobenzene, dichlorobenzene and the like, but is insoluble in methanol. A high-quality film was prepared by spin coating of a chloroform solution of the polymer PM6-TTz20 onto a glass sheet.

FIG. 2 shows the absorption spectrum of the polymer PM6-TTz in chloroform solution and as a film. The optical band gap of the polymer was calculated by the formula (E_{g}=1240/λ_{initial absorption}, where: E_{g} is the optical band gap of the polymer; and λ_{initial absorption} refers to the start of the absorption spectrum in the long-wave direction). The result is shown in Table 1.

TABLE 1
Optical absorption data of polymer PM6-TTz20

| Polymer | Maximum absorption (nm) | | Initial absorption (nm) | | E_{g}^{opt} (eV) |
|---|---|---|---|---|---|
| PM6- | Solution | Film | Solution | Film | — |
| TTz20 | 570 | 610 | 668 | 670 | 1.85 |

It can be seen from Table 1 that the maximum absorption of the polymer PM6-TTz20 in the solution occurs at 570 nm, and the initial absorption occurs at 668 nm. When the polymer PM6-TTz20 is spin-coated into a film, the maximum absorption and initial absorption occur at 610 nm and 670 nm, respectively. It shows that the polymer is aggregated to some extent in the solution. From the initial absorption of the polymer film, according to the formula E_{g}^{opt}=1240/λ_{initial absorption, film} (eV), the optical band gap of the polymer PM6-TTz20 is 1.85 eV.

2. The polymer PM6-TTz20 (1.0 mg) prepared in Example 1 was dissolved in 1 mL of chloroform, and then the solution was added dropwise to a working electrode, such as a platinum sheet. A 0.1 mol/L Bu₄NPF₆ solution in acetonitrile was used as the electrolyte, a platinum wire was used as the counter electrode, and a silver wire was used as the reference electrode. Electrochemical cyclic voltammetry was performed in this system. The cyclic voltammetry data of polymer PM6-TTz20 is shown in FIG. 3. Calculated from the results in FIG. 3, the HOMO energy level of the polymer PM6-TTz20 is −5.50 eV, and the LUMO energy level is −3.60 eV.

3. Preparation and performance test of organic solar cell devices:

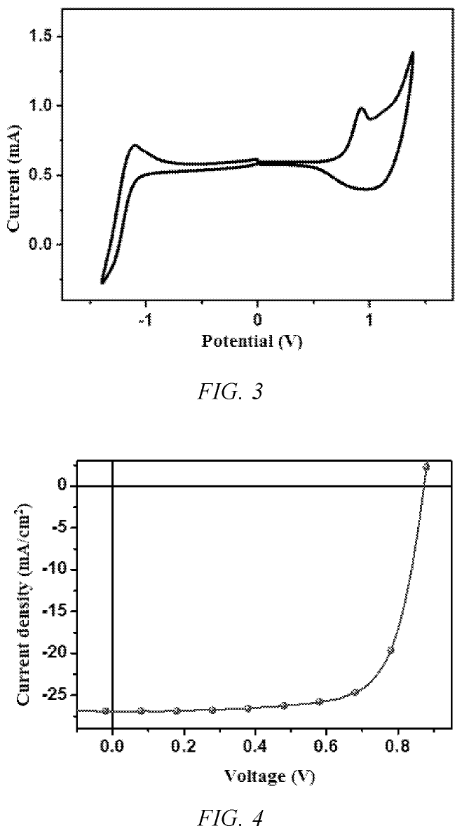

Commercially available indium tin oxide (ITO) glass was first scrubbed with acetone, then ultrasonically washed with a detergent, water, deionized water, acetone, and isopropanol in sequence. Then the ITO glass was dried, and spin-coated with a layer of 30 nm-thick PEDOT:PSS for use as an anode modification layer. A mixed solution in chloroform (10-30 mg/ml) of the terpolymer based on 2,5-bis(2-thienyl)thiazolo[5,4-d]thiazolyl in the example and a small molecule electron acceptor material Y6 (weight ratio of 1:1.25) as well as the additive chloronaphthalene (0.25%-3%) was spin-coated on the PEDOT:PSS anode modification layer to form an active layer of the device. Finally, a layer of PDINO with a thickness of about 10 nm was spin-coated as a cathode modification layer and Al (100 nm) was used as a cathode of the device to obtain a polymer solar cell device. The active area of the photovoltaic device is 0.04 cm². The energy conversion efficiency of the polymer solar cell was measured by testing the photovoltaic performance of the device using SS-F5-3A (Enli Technology CO., Ltd.) as a solar simulator at a light intensity of 100 mW/cm². The light intensity was calibrated by a standard monocrystalline silicon solar cell (SRC-00019) calibration. A J-V curve was obtained by Keithley 2450. Three parameters, including open circuit voltage, short-circuit current and fill factor, of the polymer solar cell device were tested. The J-V curve is shown in FIG. 4, where the open circuit voltage V_{oc} of the polymer solar cell device is 0.87 V, the short-circuit current J_{sc} is 26.9 mA/cm², the fill factor FF is 73%, and the conversion efficiency PCE is 17.1%.

The structure of the small molecule acceptor material Y6 used in the present invention is shown below:

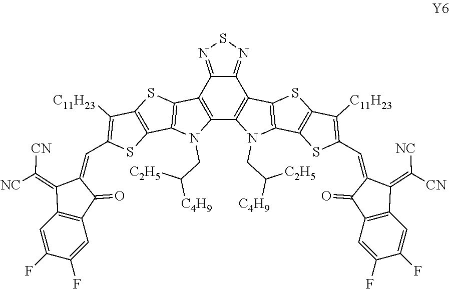

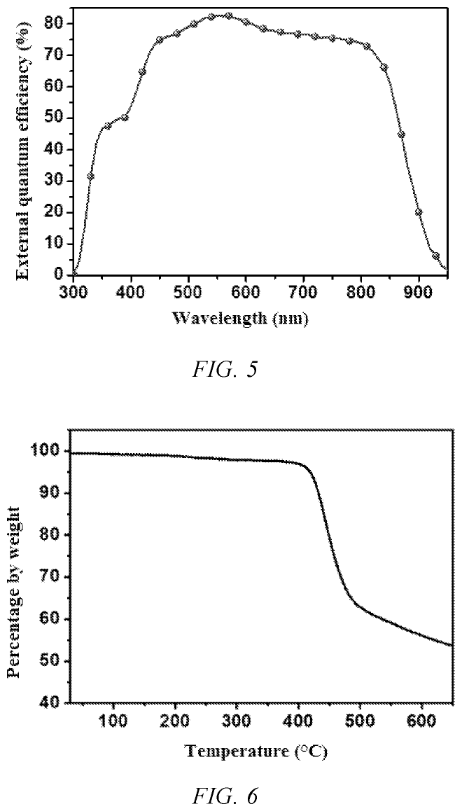

FIG. 5 is an EQE curve of an organic solar cell where the terpolymer PM6-TTz20 based on 2,5-bis(2-thienyl)thiazolo[5,4-d]thiazolyl of the present invention is used. The integrated short-circuit current obtained from the EQE curve is 24.4 mA cm⁻² and it is within 5% of the error of the test value, which indicates that the data of the device is highly reliable.

### Example 2

1. Synthesis of terpolymer PM6-TTz50

The chemical reaction route in this example is shown below, and the specific reaction steps and conditions are as follows.

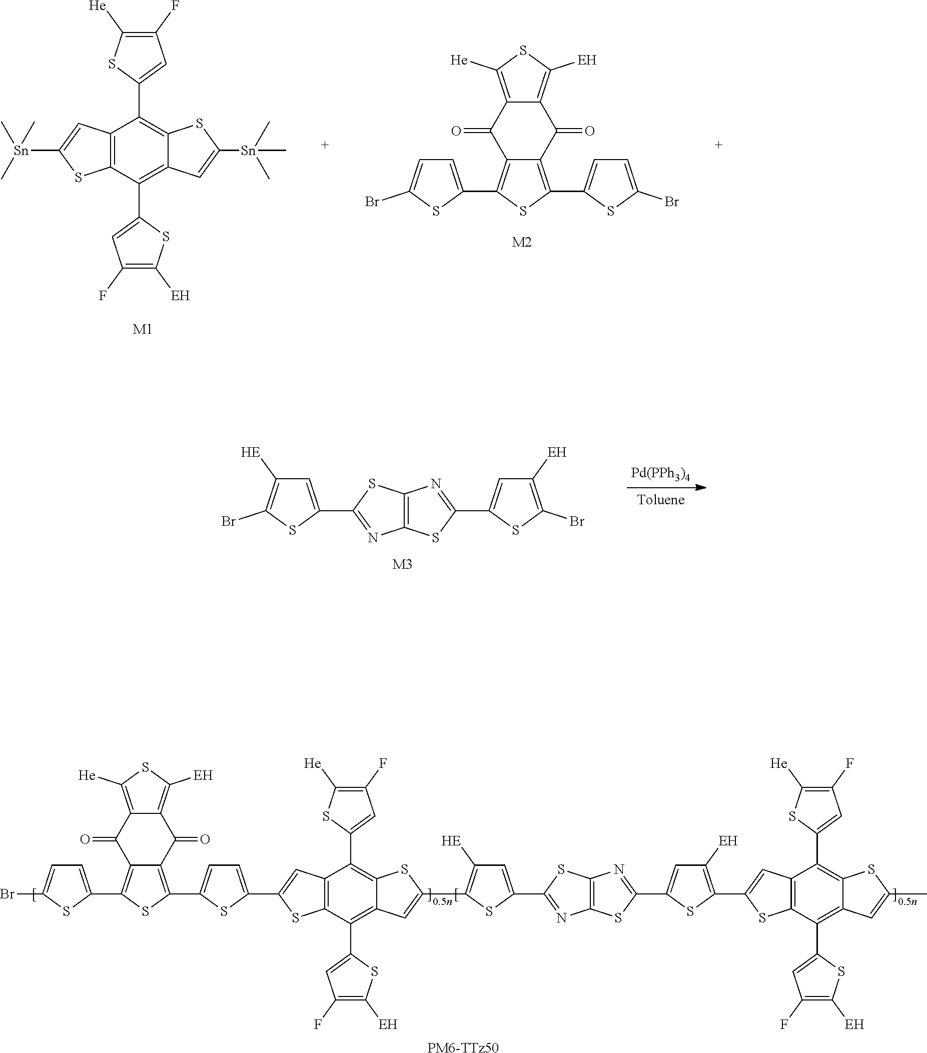

To a 50 mL two-neck round-bottom flask, 0.3 mmol of a ditin monomer M1, 0.15 mmol of a dibromide monomer M2, 0.15 mmol of a dibromide monomer M3, and 10 mL of anhydrous toluene were added. After argon was introduced for 20 min to the reaction flask, 15 mg of Pd(PPh₃)₄ was added to the flask as a catalyst, and then argon was introduced to the reaction mixture for 30 min. The reaction mixture was stirred and refluxed for 7 h under argon atmosphere. After the polymerization, the reaction mixture was cooled to room temperature, and then the polymer was settled in 100 mL of HPLC-grade methanol. The solid was collected by filtration, and finally subjected to Soxhlet extraction with HPLC-grade methanol, n-hexane and chloroform. The chloroform extract was concentrated and settled in HPLC-grade methanol, to obtain the solid polymer PM6-TTz50, which was dried under vacuum. Using trichlorobenzene as a solvent, the polymer is measured by gel permeation chromatography to have a number average molecular weight (Mₙ) of 23.2 kDa and a polydispersity index (PDI) of 2.89.

The polymer PM6-TTz50 prepared above was subjected to thermogravimetric analysis under a nitrogen atmosphere. The results are shown in FIG. 6. FIG. 6 shows that the decomposition temperature of the polymer PM6-TTz50 at a weight loss of 5% is 418° C., which indicates that the polymer has good thermal stability.

The polymer PM6-TTz50 prepared above was mixed with various organic solvents. It is found that the polymer PM6-TTz50 has good solubility in toluene, chloroform, chlorobenzene, dichlorobenzene and the like, but is insoluble in methanol. A high-quality film was prepared by spin coating of a chloroform solution of the polymer PM6-TTz50 onto a glass sheet.

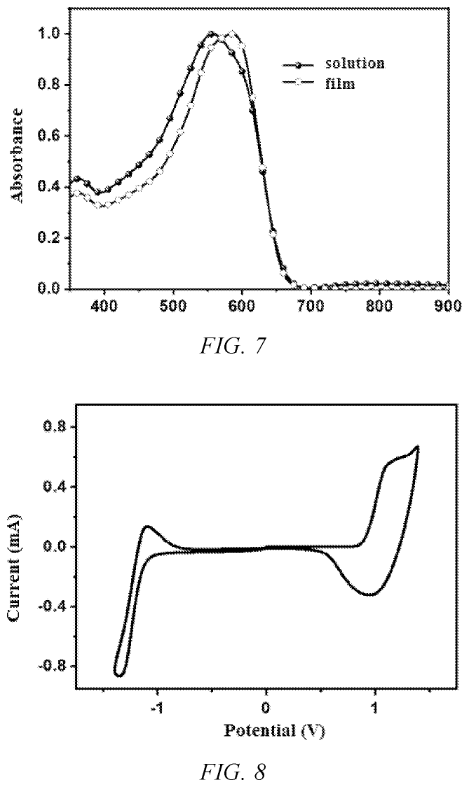

FIG. 7 shows the absorption spectra of the polymer PM6-TTz50 in chloroform and as a film. The optical band gap of the polymer was calculated by the formula (E_{g}=1240/λ_{initial absorption}, where: E_{g} is the optical band gap of the polymer; and λ_{initial absorption} is the start of the absorption spectrum in the long-wave direction). The result is shown in Table 1.

TABLE 1
Optical absorption data of polymer PM6-TTz50

| Polymer | Maximum absorption (nm) | | Initial absorption (nm) | | E_{g}^{opt} (eV) |
|---|---|---|---|---|---|
| PM6- | Solution | Film | Solution | Film | — |
| TTz50 | 554 | 586 | 656 | 656 | 1.89 |

It can be seen from Table 1 that the maximum absorption of the polymer PM6-TTz50 in the solution occurs at 554 nm, and the initial of absorption occurs at 656 nm. When the polymer PM6-TTz50 is spin-coated into a film, the maximum absorption and initial absorption occur at 586 nm and 656 nm, respectively. It shows that the polymer is aggregated to some extent in the solution. From the initial absorption of the polymer film, according to the formula E_{g}^{opt}=1240/λ_{initial absorption, film} (eV), the optical band gap of the polymer PM6-TTz50 is 1.89 eV.

2. The polymer PM6-TTz50 (1.0 mg) prepared in Example 2 was dissolved in 1 mL of chloroform, and then the solution was added dropwise to a working electrode, such as a platinum sheet. A 0.1 mol/L Bu₄NPF₆ solution in acetonitrile was used as the electrolyte, a platinum wire was used as the counter electrode, and a silver wire was used as the reference electrode. Electrochemical cyclic voltammetry was performed in this system. The cyclic voltammetry data of polymer PM6-TTz50 is shown in FIG. 8. Calculated from the results in FIG. 8, the HOMO energy level of the polymer PM6-TTz20 is −5.60 eV, and the LUMO energy level is −3.63 eV.

3. Preparation and performance test of organic solar cell devices:

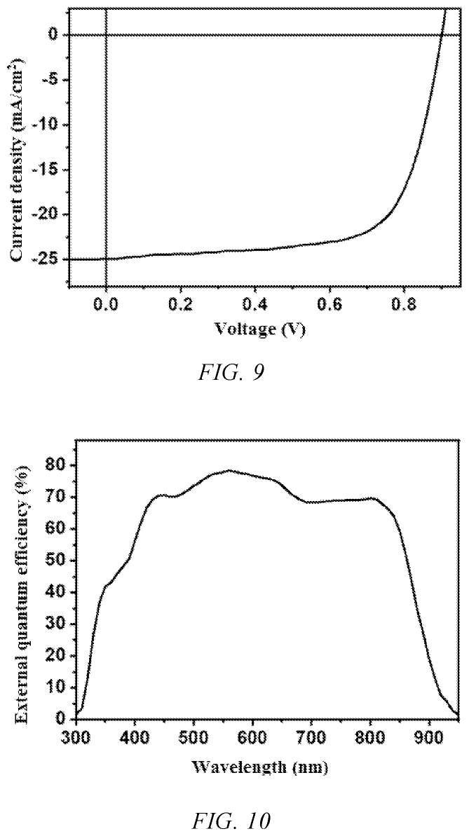

Commercially available indium tin oxide (ITO) glass was first scrubbed with acetone, then ultrasonically washed with a detergent, water, deionized water, acetone, and isopropanol in sequence. Then the ITO glass was dried, and spin-coated with a layer of 30 nm-thick PEDOT:PSS for use as an anode modification layer. A mixed solution in chloroform (10-30 mg/ml) of the terpolymer based on 2,5-bis(2-thienyl)thiazolo[5,4-d]thiazolyl in the example and a small molecule electron acceptor material Y6 (weight ratio of 1:1.25) as well as the additive chloronaphthalene (0.25%-3%) was spin-coated on the PEDOT:PSS anode modification layer to form an active layer of the device. Finally, a layer of PDINO with a thickness of about 10 nm was spin-coated as a cathode modification layer and Al (100 nm) was used as a cathode of the device to obtain a polymer solar cell device. The active area of the photovoltaic device is 0.04 cm². The energy conversion efficiency of the polymer solar cell was measured by testing the photovoltaic performance of the device using SS-F5-3A (Enli Technology CO., Ltd.) as a solar simulator at a light intensity of 100 mW/cm². The light intensity was calibrated by a standard monocrystalline silicon solar cell (SRC-00019). A J-V curve was obtained by Keithley 2450. Three parameters, including open circuit voltage, short-circuit current and fill factor, of the polymer solar cell device were tested. The J-V curve is shown in FIG. 9, where the open circuit voltage V_{oc} of the polymer solar cell device is 0.90 V, the short circuit current J_{sc} is 24.9 mA/cm², the fill factor FF is 69%, and the conversion efficiency PCE is 15.5%.

The structure of the small molecule acceptor material Y6 used in the present invention is shown below:

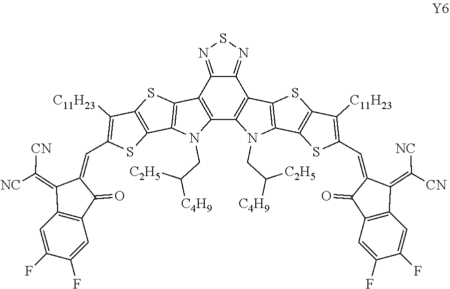

FIG. 10 is an EQE curve of an organic solar cell where the terpolymer PM6-TTz50 based on 2,5-bis(2-thienyl)thiazolo[5,4-d]thiazolyl of the present invention is used. The integrated short circuit current obtained from the EQE curve is 22.9 mA cm⁻² and it is within 5% of the error of the test value, which indicates that the data of the device is highly reliable.

Compared with the prior art, the present invention has the following beneficial effects. In the present invention, a new terpolymer based on 2,5-bis(2-thienyl)thiazolo[5,4-d]thiazolyl is prepared, which is easy to synthesize and has high yield, good solubility as well as good thermal stability. The polymer has well-adjusted molecular energy level, strong absorption spectrum and high charge transport properties, and is suitable for use as an electron donor or electron acceptor materials in the preparation of organic solar cells.

It should be noted that the above embodiments are intended to illustrate, instead of limiting the technical solution of the present invention. Although the present invention is described in detail by way of preferred examples, it should be understood by those of ordinary skill in the art that modifications or equivalent replacement can be made to the technical solutions of the present invention without departing from the spirit and scope of the technical solution of the present invention, which are all contemplated in the scope of the present invention as defined by appended claims.

What is claimed is:

1. A terpolymer based on 2,5-bis(2-thienyl)thiazolo[5,4-d]thiazolyl, having a general formula of: 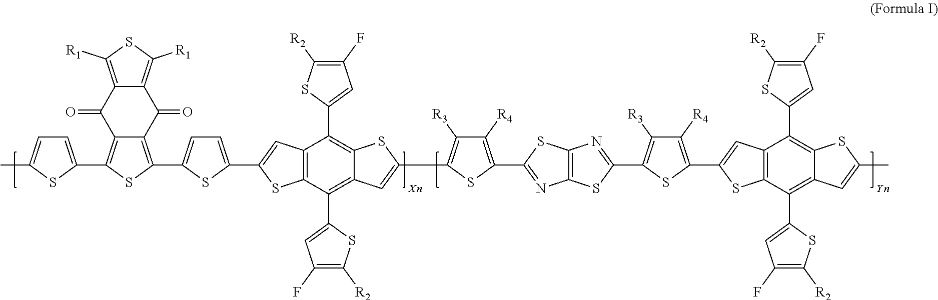
wherein:
R₁ is an alkyl group having 1-30 carbon atoms;
R₂, R₃ and R₄ are independently selected from the group consisting of hydrogen, an alkyl group having 1-30 carbon atoms, an alkoxy group having 1-30 carbon atoms, an ester group, an aryl group, an aralkyl group, a haloalkyl group, a heteroalkyl group, an alkenyl group and an aryl group substituted by a substituent group containing a single bond, a double bond, a triple bond or any combination thereof;
n represents the number of repeating units in the polymer, and is selected from a natural number between 1-5000; and
X and Y are independently selected from decimals between 0-1, and the sum of X and Y is equal to 1.

2. The terpolymer based on 2,5-bis(2-thienyl)thiazolo[5,4-d]thiazolyl according to claim 1, wherein the terpolymer has a number average molecular weight of 1000 to 1,000,000.

3. A method for preparing a terpolymer based on 2,5-bis(2-thienyl)thiazolo[5,4-d]thiazolyl, comprising subjecting a compound of Formula II, a compound of Formula III, and a compound of Formula IV to ternary random copolymerization in the presence of a catalyst: 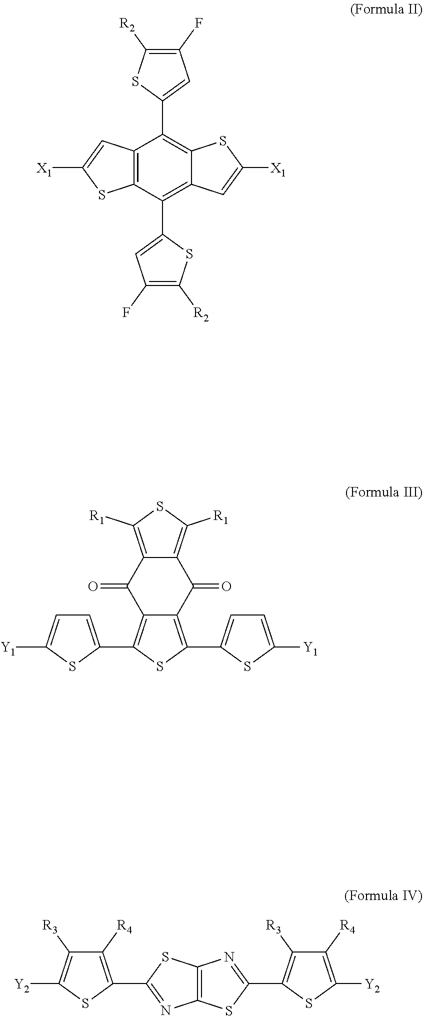
wherein:
R₁ is selected from an alkyl group having 1-30 carbon atoms;
R₂, R₃ and R₄ are independently selected from the group consisting of hydrogen, an alkyl group having 1-30 carbon atoms, an alkoxy group having 1-30 carbon atoms, an ester group, an aryl group, an aralkyl group, a haloalkyl group, a heteroalkyl group, an alkenyl group, and an aryl group substituted by a substitute group containing a single bond, a double bond, a triple bond or any combination thereof;
X₁ is selected from the group consisting of a boric acid group, a borate ester group, a zinc halide group and a trialkyltin group; and
Y₁ and Y₂ are independently selected from I, Br or Cl.

4. The method for preparing a terpolymer based on 2,5-bis(2-thienyl)thiazolo[5,4-d]thiazolyl according to claim 3, wherein the boric acid group is selected from 1,3,2-dioxaboran-2-yl, 4,4,5,5-tetramethyl-1,2,3-dioxaborolan-2-yl or 5,5-dimethyl-1,3,2-dioxaboran-2-yl; the zinc halide group is selected from zinc chloride group or zinc bromide group; and the trialkyltin group is selected from trimethyl tin, triethyl tin or tributyl tin.

5. The method for preparing a terpolymer based on 2,5-bis(2-thienyl)thiazolo[5,4-d]thiazolyl according to claim 3, wherein the catalyst is selected from the group consisting of [1,3-bis(diphenylphosphino)propane]nickel dichloride, tetrakis(triphenylphosphine)palladium, [1,2-bis(diphenylphosphino)ethane]nickel chloride, bis(dibenzalacetone)palladium, palladium chloride, palladium acetate and any combination thereof.

6. The method for preparing a terpolymer based on 2,5-bis(2-thienyl)thiazolo[5,4-d]thiazolyl according to claim 3, wherein the molar ratio of the compound of Formula III to the compound of Formula IV is 100:0-100:100 to 0:100-100:100.

7. The method for preparing a terpolymer based on 2,5-bis(2-thienyl)thiazolo[5,4-d]thiazolyl according to claim 3, wherein the reaction temperature is 80-200° C., and the reaction time is 6-48 h.

8. Use of the terpolymer based on 2,5-bis(2-thienyl)thiazolo[5,4-d]thiazolyl in thin film semiconductor devices, electrochemical devices, photovoltaic devices and photoelectric devices.
